(19) United States
(12) Patent Application Publication
(10) Pub. No.: US 2013/0043862 A1
(43) Pub. Date: Feb. 21, 2013

(54) BIOSENSOR DETECTING THIOL GROUP AND METHOD FOR PREPARING THE BIOSENSOR

(71) Applicants: Sang Hyun Park, Daejeon (KR); Yeon Jun Jeong, Seoul (KR)

(72) Inventors: Sang Hyun Park, Daejeon (KR); Yeon Jun Jeong, Seoul (KR)

(73) Assignee: KOREA ATOMIC ENERGY RESEARCH INSTITUTE, Daejeon (KR)

(21) Appl. No.: 13/587,456

(22) Filed: Aug. 16, 2012

(30) Foreign Application Priority Data
Aug. 18, 2011 (KR) 10-2011-0082432

(51) Int. Cl. G01R 19/00; B05D 5/12; B82Y 15/00; B82Y 40/00

(52) U.S. Cl. 324/76.11; 427/561; 977/920; 977/901

(57) ABSTRACT

There is provided a biosensor for detecting a thiol group and a method of manufacturing the biosensor. In detail, in the method, Au nano particles are manufactured by irradiating radiation (Step 1), a PTh-EDOT/ITO film is manufactured by forming a poly(thiophene-co-3,4-ethylenedioxythiophene) (PTh-EDOT) layer on an indium tin oxide (ITO) coated substrate using cyclic voltammetry (CV) (Step 2) (Step 2); and a Au nano particle modified PTh-EDOT/ITO film is manufactured by dispersing the Au nano particles manufactured in Step 1 onto the PTh-EDOT/ITO film manufactured in Step 2 (Step 3).

### CROSS-REFERENCE TO RELATED APPLICATIONS

This application claims priority from Korean Patent Application No. 10-2011-0082432, filed on Aug. 18, 2011, in the Korean Intellectual Property Office, the disclosure of which is incorporated herein by reference.

### BACKGROUND OF THE INVENTION

1. Field of the Invention

The present invention relates to a biosensor detecting a thiol group and a method of preparing the biosensor.

2. Description of the Related Art

Oxidative stress caused by an imbalance between supplying active oxygen species and a biological system for effectively detoxifying the reactive intermediates damages the biological system. Disturbances in the normal redox state of cells can cause toxic effects through the production of peroxides and free radicals that damage all components of the cell, including proteins, lipids, and DNA. One source of reactive oxygen under normal conditions in humans is the leakage of activated oxygen from mitochondria during oxidative phosphorylation Also, various physical and chemical materials such as stress, drugs, cigarette smoke, radiation, exposure to a heavy metal, and certain foods may cause the occurrence of active oxygen species in the human body. Active oxygen species include hydroxyl radicals, lipid oxyl, peroxyl radicals, singlet oxygen, and more particularly, peroxynitrites formed from nitrogen oxides. The molecules above act as an individual, called as free radicals. A chemical state thereof indicates a species capable of existing independently, including one or more unpaired electrons filling one of an atomic orbital and a molecular orbital with themselves. The materials are formed from a non-radical losing a single electron or a non-radical obtaining a single electron. In humans, oxidative stress may cause many diseases such as atherosclerosis, Parkinson's disease, heart failure, myocardial infarction, Alzheimer's disease, and chronic fatigue syndrome.

One of primary results from the occurrence of active oxygen species in a biological system is lipid peroxide (LPO). The LPO refers to the oxidative degradation of lipids, occurring due to free radicals stealing electrons from the lipids in cell membranes. The process proceeds by a free radical chain reaction mechanism inducing absolute destruction of cell membrane structures to make cells wither. Primary bi-products of LPO are malondialdehyde (MDA) formed by preoxidation of poly unsaturated fatty acid in cell membranes. It has been determined through many researches that an increase of the MDA reflects oxidative stress in a human body. The MDA has been used to estimate at state of LPO caused by the occurrence of exogenous free radicals or endogenous active oxygen species. Accordingly, a reason of picking the MDA as a biomarker is based on that only the MDA is generated from lipid peroxide and a change in concentration of the MDA reflects a variation in the level of lipid oxidation. A thiobarbituric acid (TBA) test has been used for 40 years to detect and quantify LPO from not only various chemicals but also a biological specimen. The TBA test may quantify fluorescent red additives (2TBA-MDA additives) through one of spectroscopic analysis and chromatography analysis, based on reactivity of the TBA with respect to the MDA.

Korean Patent Application No. 10-2010-0004954 (hereinafter, referred to as Cited Reference 1) relates a two-photon fluorescent probe including 2-methyamino-6-acethylnaftalene as a reporter and a disulfide group as a thiol reaction site, shown as the following Chemical formula 1, and discloses a method of detecting a thiol with high selectivity, the thiol existing in a biological cell and tissue with a depth of 90 to 180 μm.

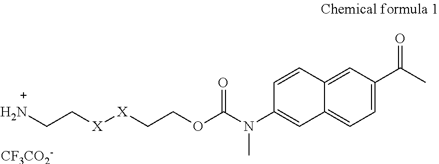

In Chemical formula 1, X═S (sulfur).

Korean Patent Application No. 10-2007-0128477 (hereinafter, referred to as Cited Reference 2) discloses a method of manufacturing a sensor chip using surface Plasmon resonance (SPR) technology, a sensor chip manufactured using the method, and a method of detecting biomaterials using the sensor chip, the sensor chip manufacturing method including the steps: forming an intermediate film by introducing an organic single-molecule having one of amine (—NH₂) and a thiol (—SH) functional group on a gold chip and adsorbing gold colloid onto the organic single-molecule by dipping the intermediate film in a gold colloid solution; fixing fusion protein with gold-binding protein (GBP) bound with one of protein A and protein G on the gold colloid substrate; and specifically binding the fixed fusion protein with an antibody.

The present inventors has developed a method of detecting a thiol group by mutual binding between the thiol group and gold nano particles while studying a method of detecting a thiol group using 2TBA-MDA.

### SUMMARY OF THE INVENTION

An aspect of the present invention provides a biosensor for detecting a thiol group.

An aspect of the present invention also provides a method of manufacturing the biosensor for detecting a thiol group.

According to an aspect of the present invention, there is provided a biosensor for detecting a thiol group, the biosensor where ITO, PTh-EDOT, and an Au nano particle films sequentially laminated on.

According to another aspect of the present invention, there is provided a method of manufacturing the biosensor for detecting a thiol group. In the method, Au nano particles are manufactured by irradiating radiation (Step 1), a PTh-EDOT/ITO film is manufactured by forming a poly(thiophene-co-3,4-ethylenedioxythiophene) (PTh-EDOT) layer on an indium tin oxide (ITO) coated substrate using cyclic voltammetry (CV) (Step 2); and an Au nano particle modified PTh-EDOT/ITO film is manufactured by dispersing the Au nano particles manufactured in Step 1 onto the PTh-EDOT/ITO film manufactured in Step 2 (Step 3).

The biosensor and the method of manufacturing the biosensor according to the present invention provide effects as follows. A thiol group may be detected using intercombination between the thiol group and gold nano particles, simply detected using CV. Due to noticeable detectability, it is possible to protect human beings from many diseases such as atherosclerosis, Parkinson's disease, heart failure, myocardial infarction, Alzheimer's disease, and chronic fatigue syndrome by determining the degree of oxidative stress of a human body.

### BRIEF DESCRIPTION OF THE DRAWINGS

The above and/or other aspects and advantages of the present invention will become apparent and more readily appreciated from the following detailed description, taken in conjunction with the accompanying drawings of which:

FIG. 1 is a schematic diagram illustrating a process of manufacturing a biosensor for detecting a thiol group and the biosensor bound with a thiol group;

FIGS. 2A to 2D illustrate results of growing PTh, PEDOT, and PTh-EDOT films on an ITO electrode;

FIG. 3 is a graph illustrating electrochemical reduction of Au ions at PTh-EDOT for 15 cycles in the biosensor of FIG. 1;

FIGS. 4A to 4C are SEM photos of Au nano particles formed on a of PTh-EDOT/ITO surface in the biosensor of FIG. 1;

FIGS. 5A and 5B illustrate EDX spectra of the biosensor of FIG. 1;

FIGS. 6A and 6B illustrates results of observation using an atomic force microscopy of Embodiments 1 and 2 that are the biosensors of FIG. 1;

FIG. 7 illustrates an XRD pattern of Au/PTh-EDOT/ITO, PTh-EDOT/ITO, and ITO; and

FIGS. 8A to 8D illustrate cyclic voltammetry of the biosensor of FIG. 1 and the biosensor bound with a thiol group.

### DETAILED DESCRIPTION OF THE INVENTION

Hereinafter, the present invention will be described in detail.

According to an embodiment of the present invention, there is provided a biosensor for detecting a thiol group, where ITO, PTh-EDOT, and Au nano particles are sequentially laminated on.

Oxidative stress caused by an imbalance between supplying active oxygen species and a biological system for effectively detoxifying the reactive intermediates damages the biological system. Active oxygen species may be induced by various physical and chemical materials such as stress, drugs, cigarette smoke, radiation, exposure to a heavy metal, and certain foods. One of primary results from the occurrence of active oxygen species in a biological system is lipid peroxide (LPO). Primary bi-products of LPO are malondialdehyde (MDA) formed by preoxidation of poly unsaturated fatty acid in cell membranes. An increase of the MDA indicates the occurrence of oxidative stress in a human body. To detect the MDA, a thiobarbituric acid (TBA) test is performed to quantify reactivity of the TBA with respect to the MDA through one of spectroscopic analysis and chromatography analysis for fluorescent red additives (2TBA-MDA additives). However, in case of the present invention, a thiol group of the TBA is detected directly, thereby inferring a degree of oxidative stress. In more detail, the biosensor according to the present invention may detect a thiol group using a mutual bond between the thiol group and gold nano particles using cyclic voltammetry (CV).

Also, according to an embodiment of the present invention, there is provided a method of manufacturing a biosensor for detecting a thiol group. The method includes: manufacturing Au nano particles using irradiating radiation (Step 1); manufacturing a PTh-EDOT/ITO film by forming a poly(thiophene-co-3,4-ethylenedioxythiophene) (PTh-EDOT) layer on an indium tin oxide (ITO) coated substrate using cyclic voltammetry (CV) (Step 2) (Step 2);

and manufacturing an Au nano particles modified PTh-EDOT/ITO film by dispersing the Au nano particles manufactured in Step 1 on the PTh-EDOT/ITO film manufactured in Step 2 (Step 3).

Hereinafter, there will be described in detail the method of manufacturing the biosensor for detecting a thiol group according to an embodiment of the present invention.

In the method of manufacturing the biosensor for detecting a thiol group, Step 1 is a process of manufacturing Au nano particles by irradiating radiation. The Au nano particles in Step 1 may be manufactured using polyvinylpyrrolidine (PVP) that is a nano particle stabilizing polymer stabilizing nano particles. For example, the PVP, HAuCl₄, and isopropanol are mixed and radiation is irradiated thereto, thereby manufacturing Au nano particles. In this case, the radiation may be irradiated using γ-ray of co-60 with a dose-rate of 6×10⁵ to 7×10⁵ Gy/h, adding up to a total absorption dose rate of 15 to 35 kGy. When the total absorption dose rate is less than 15 kGy, a size of manufactured Au nano particles become increased. When the total absorption dose rate is more than 35 kGy, there is no noticeable effect on the size of nano particles, which causes an economic loss due to expenses for an unnecessary process.

In the method of manufacturing the biosensor for detecting a thiol group, Step 2 is a process of manufacturing a PTh-EDOT/ITO film by forming a poly(thiophene-co-3,4-ethylenedioxythiophene) (PTh-EDOT) layer on an indium tin oxide (ITO) coated substrate using cyclic voltammetry (CV). In this case, the ITO-coated substrate, and more particularly, a glass substrate is cleansed using ultrasonic waves, a Th-EDOT monomer and tetrabutylammonium perchlorate are added into an acetonitrile solution, and the polymerization using CV in Step 2 may be performed in a three-compartment cell within a voltage range of +1.0 to +2.5 V. When the voltage is less than +1.0 V, a polymerization reaction does not occur. When the voltage is more than +2.5 V, PEDOT is polymerized on a top of a PTh film.

Also, the Th-EDOT monomer may have a molar ratio of Th to EDOT as 4 to 6:1. When a Th molar fraction of the Th-EDOT monomer is less than 4, a PTh film is not formed well. When a Th molar fraction of the Th-EDOT monomer is more than 6, PEDOT is polymerized later than PTh.

In the method of manufacturing the biosensor for detecting a thiol group, Step 3 is a process of manufacturing an Au nano particle modified PTh-EDOT/ITO film by dispersing the Au nano particles manufactured in Step 1 on the PTh-EDOT/ITO film manufactured in Step 2. The binding between the PTh-EDOT/ITO film and the Au nano particles in Step 3 may be performed using one of a chemical adsorption method and an electrochemical reduction method. The chemical adsorption may be performed by dispersing a polymer solution containing Au nano particles to the PTh-EDOT/ITO film manufactured in Step 2. The electrochemical reduction may be performed using CV within a voltage range of −12.5 to −3.0 V in an Au salt solution, and more particularly, a KCl solution containing HAuCl₄. When the electrochemical reduction is performed with a voltage out of the voltage range, electrical durability of a PTh-EDOT film is deteriorated.

Hereinafter, exemplary embodiments of the present invention will be described in detail. However, the following embodiments are just for description and the scope of the present invention will not be limited thereto.

### <Embodiment 1> Manufacturing Biosensor for Detecting Thiol Group

Step 1: Manufacturing Au Nano Particles

A polypropylene bottle of 250 ml was cleansed using distilled water in ultrasonic waves, 1 g of HAuCl₄ (1.0×10⁻³M), 1 g of PVP (MW=10,000), and 20 ml of isopropanol were put into the polypropylene bottle, 180 ml of distilled water was added, and mixed them by magnetic stirring. To remove oxygen, a mixed solution effervesced for 10 minutes due to a nitrogen gas. The mixed solution was irradiated with γ-ray from a Co60 source under atmospheric pressure at room temperature, whose total absorption dose rate was 25 kGy (a dose rate=6.48×10⁵/h), thereby manufacturing Au nano particles stabilized with polyvinylpyrrolidine (M.W.=58,000, PVP).

Step 2: Forming PTh-EDOT Film on ITO Coated Substrate

A glass substrate coated with ITO was cleansed with ultrasonic waves in a detergent, deionized water, acetone, and isopropyl alcohol for 5 minutes, respectively. The ITO coated glass substrate was UV-ozone treated for 10 minutes. 0.05 M of Th-EDOT monomer with a molar ratio of Th to EDOT as 5:1 and 0.05 M of tetrabutylammonium perchlorate (TBAP) were added to an acetonitrile (AN) solution. A PTh-EDOT film was formed on 20 mm×10 mm of the ITO coated glass substrate by using CV within a voltage range of +1.0 to +2.5 V at room temperature in a three-compartment cell.

Step 3: Manufacturing Au Nano Particle Modified PTh-EDOT/ITO Film

The Au nano particles manufactured above were dispersed on a PTh-EDOT electrode, maintained for 24 hours to be fixed by chemical adsorption, and dried removing Au nano particles not fixed, thereby manufacturing a biosensor capable of detecting a thiol group.

### <Embodiment 2> Manufacturing Biosensor for Detecting Thiol Group 2

Different from Step 2 of Embodiment 1, a PTh-EDOT electrode is modified with Au nano particles using CV within a voltage range of −12.5 to −3.0 V in 0.1 M of a KCl solution containing 0.001 M of HAuCl₄ with 50 mV/s scan rate for 15 cycles. Except for this, a biosensor was manufactured performing the same process with that of Embodiment 1.

### <Embodiment 3> Manufacturing Biosensor Bound with Rhiol Group

To perform an experiment for detecting a thiol group using the biosensor manufactured in Embodiment 1, 1-decantthiol was fixed using the following method, thereby manufacturing a biosensor bound with a thiol group. In the method of fixing the 1-decanthiol, the 1-decanthiol was dropped onto an Au/PTh-EDOT electrode manufactured in Embodiment 1, maintained for 2 hours, bound by chemical adsorption between Au and -SH group, and dried cleansing 1-decanthiol not fixed to the Au/PTh-EDOT electrode.

### <Embodiment 4> Manufacturing Biosensor Bound with Thiol Group 2

A biosensor bound with 1-decanthiol was manufactured by fixing the 1-decanthiol to the biosensor manufactured in Embodiment 2 using the same method as that of Embodiment 3.

Hereinafter, the exemplary embodiments of the present invention will now be described in detail with reference to the attached drawings in such a way that the technical thoughts of the present invention may be easily carried out by those skilled in the art.

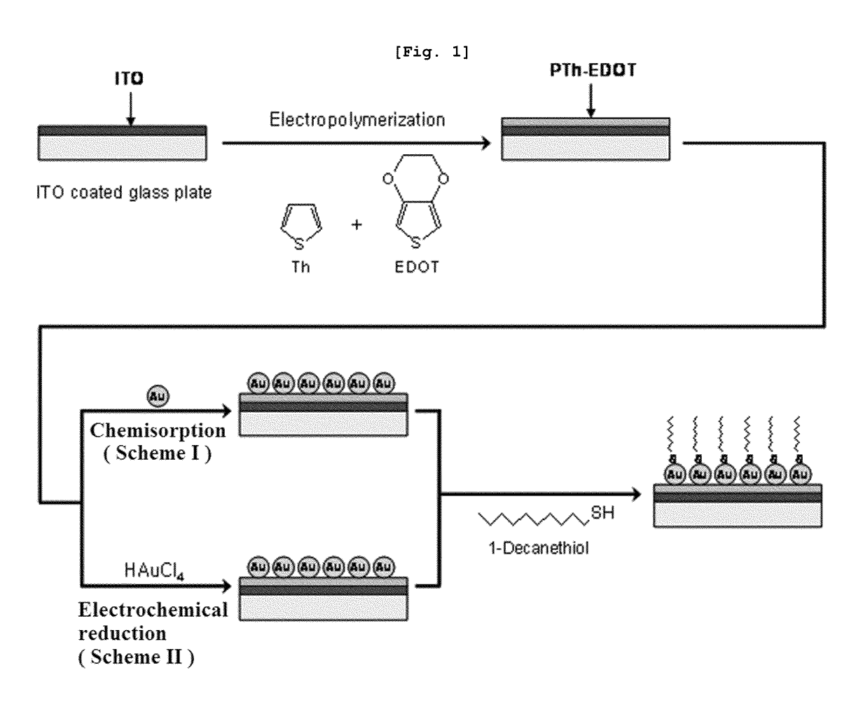

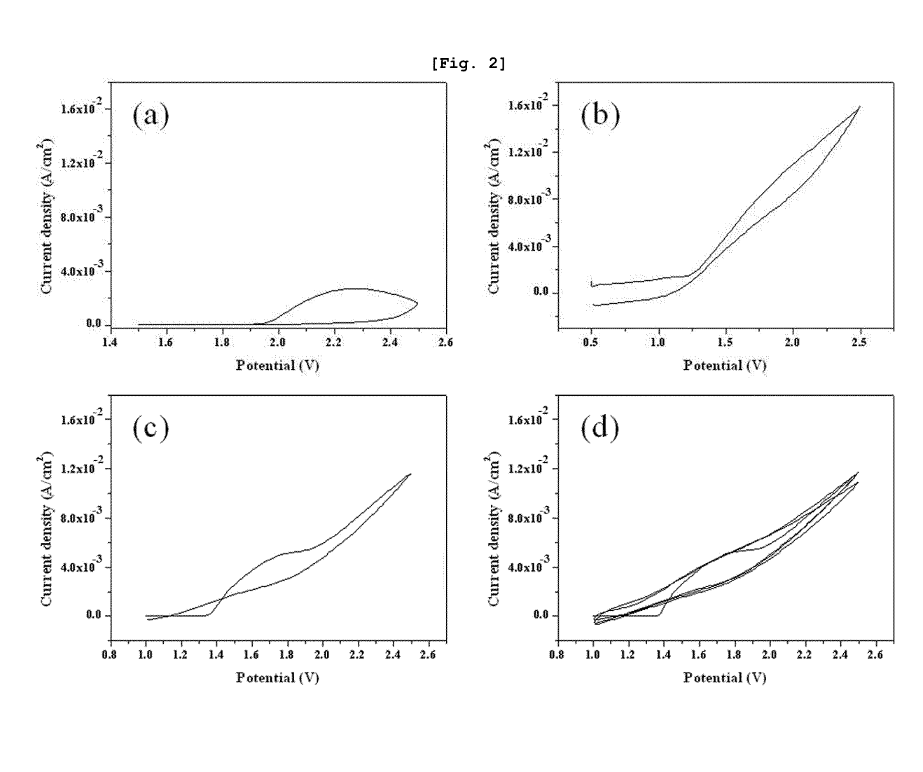

FIG. 1 illustrates a process of manufacturing a biosensor for detecting a thiol group and the biosensor bound with a thiol group. FIGS. 2A to 2D illustrate results of growing PTh, PEDOT, and PTh-EDOT films on an ITO electrode. FIG. 2A illustrates a Th monomer, FIG. 2B illustrates an EDOT monomer, and FIGS. 2C and 2D illustrate Th:EDOT=5:1 monomer.

Referring to FIG. 2A, oxidization of the Th monomer started at 1.8 V and a current drop at 2.25 V or more was due to a decrease of oxidized monomers around an operating electrode. In case of the EDOT monomer, an onset potential was 1.3 V (refer to FIG. 2B) and an onset potential value indicates that the oxidization of Th was more difficult than that of EDOT. As a result thereof, a 3,4-ethylenedioxy (3,4-ED) substituent puts out an electron, prevents a possibility of an unexpected grafting reaction, and decreases oxidization potential. To solve the above problem, a molar ratio of Th-EDOT applied to electrical polymerization of PTh-EDOT is higher than 1. FIGS. 2C and 2D illustrate that onset oxidization potentials and oxidization current density of the Th-EDOT monomer have values between pure Th and EDOT. An initial inclination of positive and negative curves with respect to Th-EDOT is similar to that of PEDOT, in which the oxidization of an EDOT monomer is stronger in case of Th-EDOT.

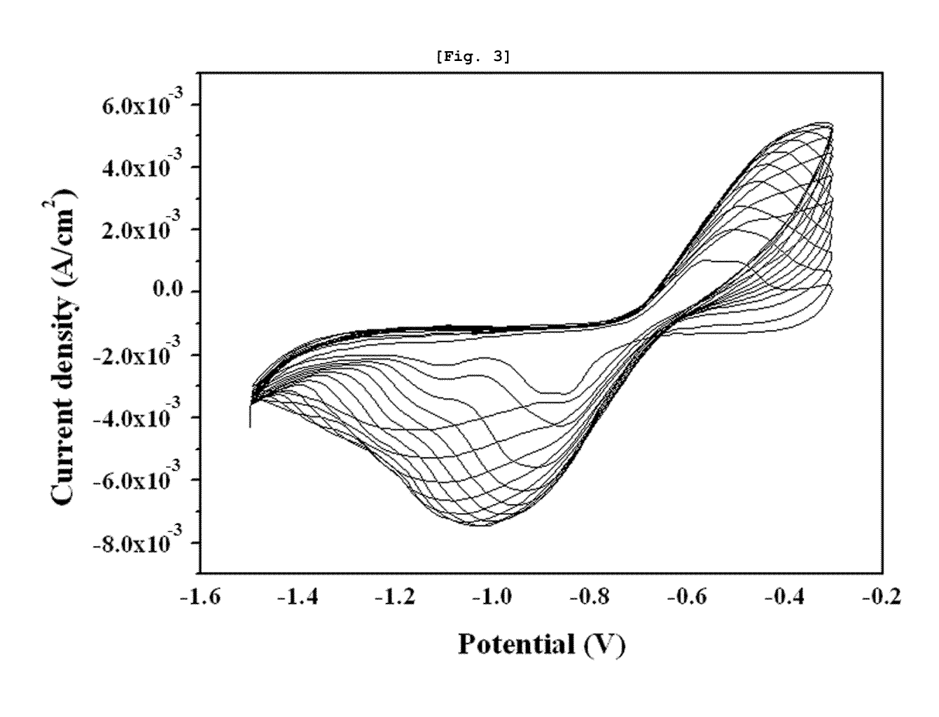

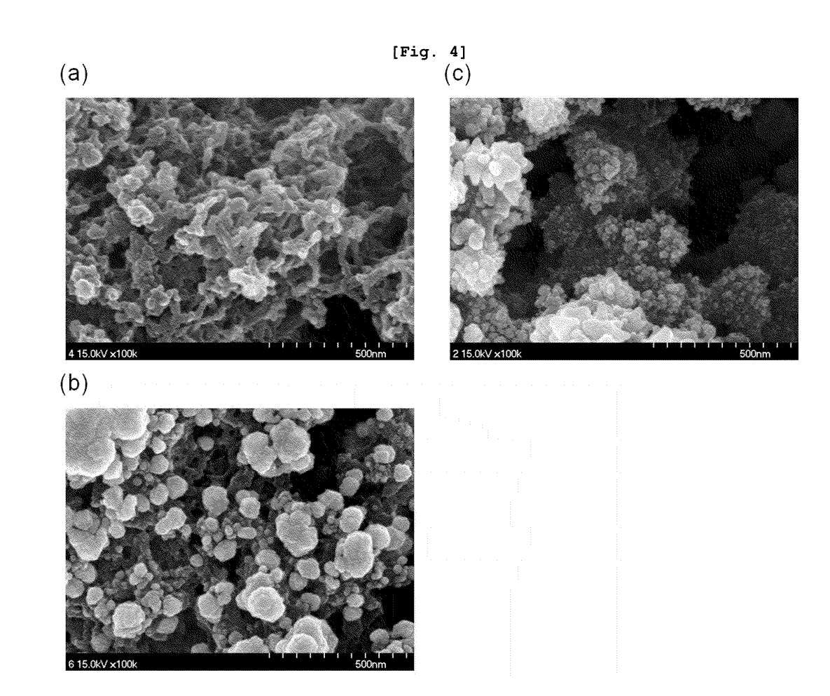

FIG. 3 illustrates electrochemical reduction of Au ions in a PTh-EDOT electrode for 15 cycles in the biosensor for detecting a thiol group. FIGS. 4A to 4C are SEM photos of Au nano particles formed on a PTh-EDOT/ITO surface in the biosensor for detecting a thiol group. FIG. 4A illustrates PTh-EDOT/ITO, FIG. 4B illustrates an Au/PTh-EDOT/ITO biosensor of Embodiment 1. An SEM photo of an electrically polymerized surface of PTh-EDOT presents that a PTh-EDOT surface is formed of a porous structure to allow ions to be quickly diffused within and without a polymer. FIG. 4C is an SEM photo of the Au/PTh-EDOT/ITO biosensor manufactured in Embodiment 2. Referring to FIGS. 4A to 4C, it may be known that Au nano particles are dispersed on the PTh-EDOT surface with a diameter of 30 to 150 nm. On Pth-EDOT, a diameter of Au nano particles is about 20 to 100 nm. It may be known that the diameter of Au nanoparticles is smaller than that of the Au/PTh-EDOT/ITO in Embodiment 1. Also, it may be known that an aspect ratio of Au of the Au/PTh-EDOT/ITO in Embodiment 1 is higher than that of Au/PTh-EDOT/ITO in Embodiment 2.

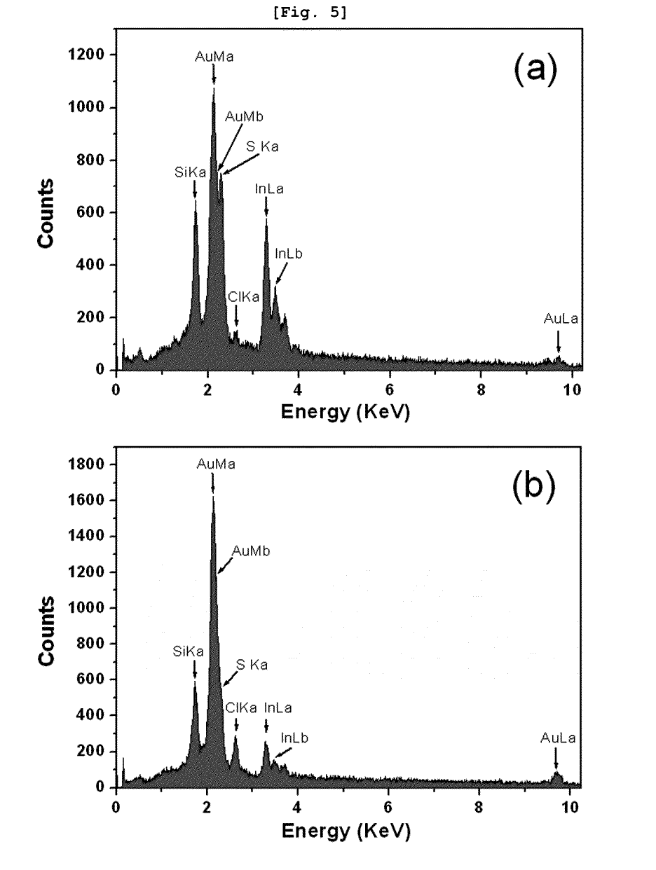

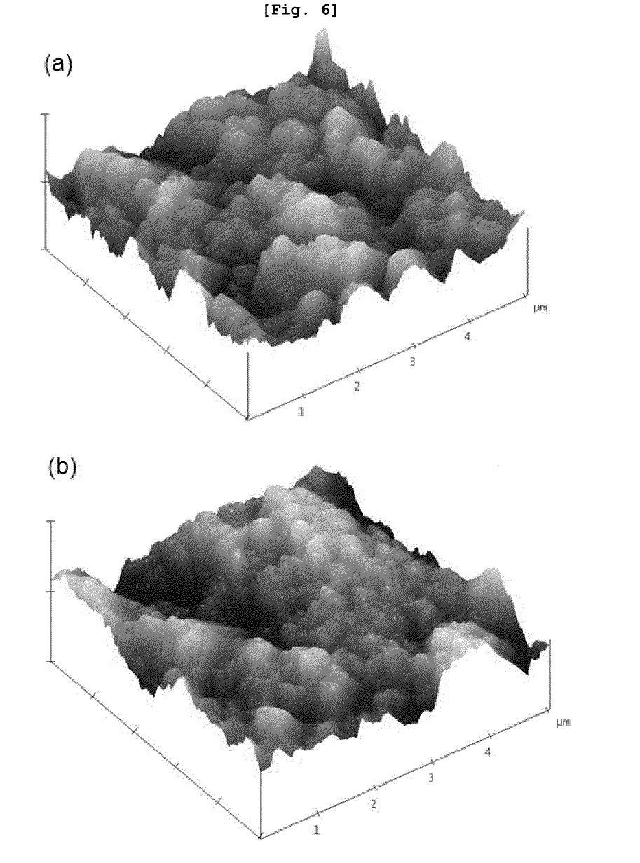

FIGS. 5A and 5B illustrate EDX spectrums of the biosensors of Embodiments 1 and 2, respectively. Referring to FIGS. 5A and 5B, AuMa, AuMb, and AuLa from Au atoms are observed as strong signals in Au/PTh-EDOT/ITO and S atoms are observed as weak signals SKs and SKb in PTh-EDOT and InLa, InLb, SiKa, and SiKb in ITO. FIGS. 6A and 6B illustrate observing results of Embodiments 1 and 2 using atomic force microscopy. Referring to FIGS. 6A and 6B, it may be known that surficial roughness of the Au/PTh-EDOT in Embodiment 1 is higher than that of the Au/PTh-EDOT in Embodiment 2.

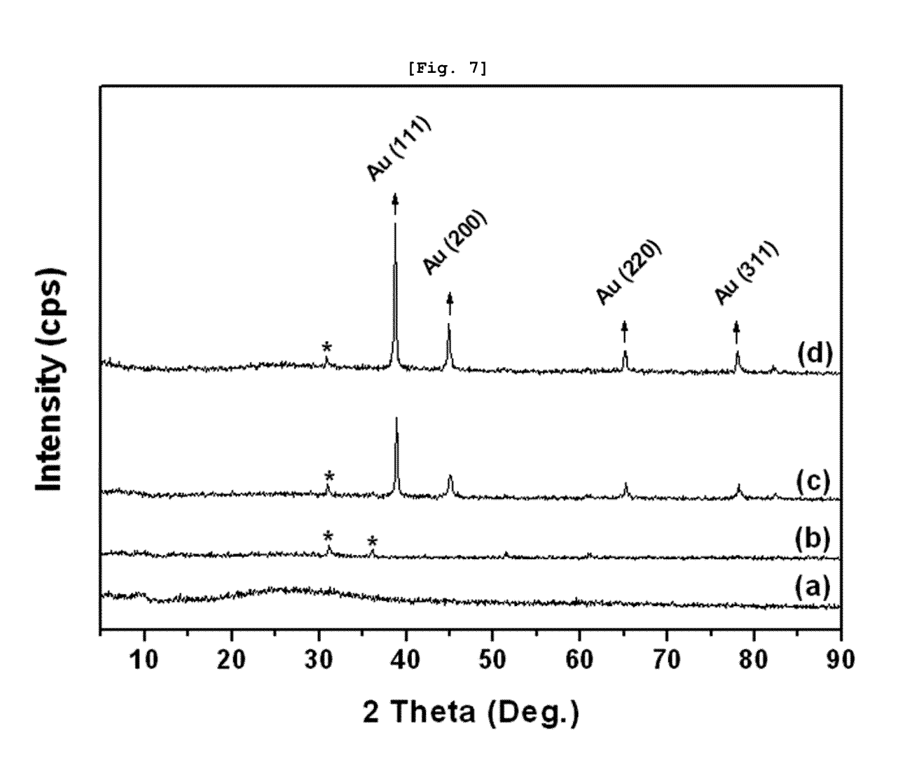

FIG. 7 illustrates XRD patterns of Au/PTh-EDOT/ITO, PTh-EDOT/ITO, and ITO. Referring to FIG. 7, (a) relates to an ITO glass substrate, (b) relates to a PTh/ITO, (c) relates to Au/PTh-EDOT/ITO in Embodiment 1, and (d) relates to Au/PTh-EDOT/ITO in Embodiment 2. Referring to FIG. 7, the ITO glass substrate of (a) shows an amorphous structure. PTh-EDOT/ITO of (b) has peaks in which 2 θ indicate regularity between molecules at 31.2° and 36.1°. This is because a copolymer has a regularly repeated structure and a regular structure in a solid state. Polythiophene (PT) also has a regular structure in a solid state, known from an XRD peak, which is explained by a rhombic system of a polymer.

Referring to FIGS. 7C and 7D, 2θ presents XRD peaks of the Au/PTh-EDOT/ITO at 38.7°, 44.9°, 65.0°, and 78.0°, in which a diffraction occurs at (111), (200), (220), and (311) of Au metal with a face-centered cubic structure. A crystal is calculated as 9.8 nm in diameter using the following Equation 1, Sherrer formula.

$${L}_{hkl} = \frac{K λ}{{β}_{hkl} cos {θ}_{hkl}} ,$$

in which K indicates 0.89, λ indicates a wave-length of X-ray, β indicates a half-power width, θ indicates Bragg angle, and h, k, and l indicate lattice constants.

The result presents that Au nano particles with a size of 20 to 150 nm consist of crystals with a size of 10 nm and Au nano particles effectively bind with a PTh-EDOT film.

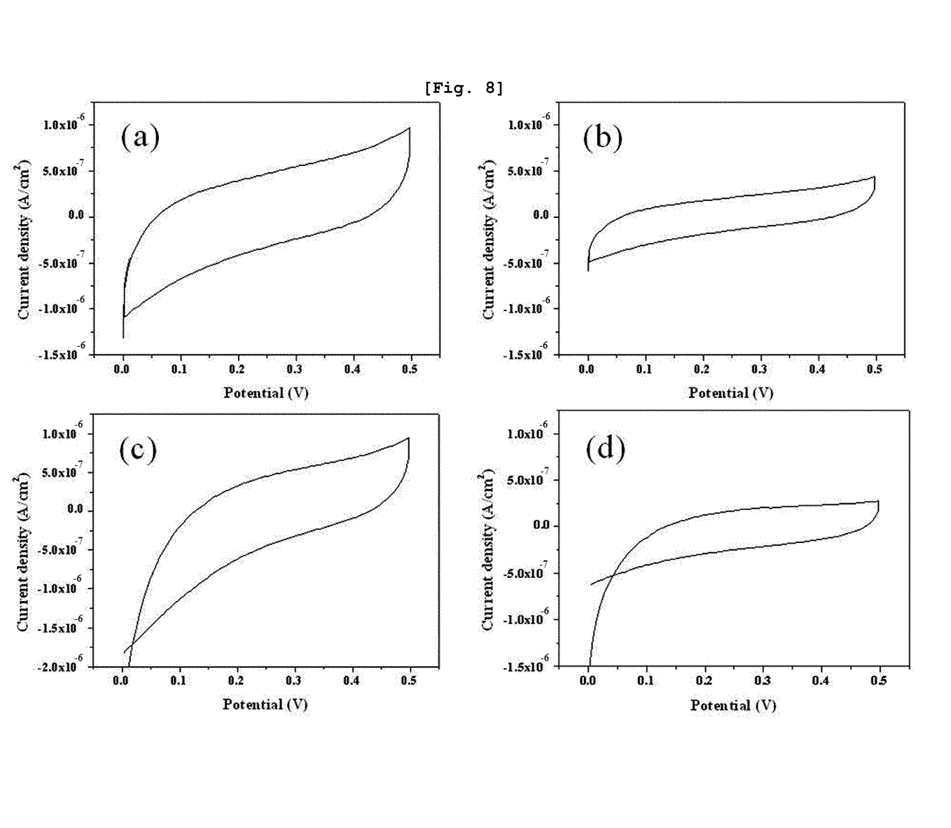

FIGS. 8A to 8D are graphs illustrating cyclic voltage-current curves of the biosensor for detecting a thiol group. FIG. 8A relates to Au/PTh-EDOT/ITO in Embodiment 1, FIG. 8B relates to DT/Au/PTh-EDOT/ITO in Embodiment 3, FIG. 8C relates to Au/PTh-EDOT/ITO in Embodiment 2, and FIG. 8D relates to DT/Au/PTh-EDOT/ITO.

To measure reversibility of an electrochemical reaction at an interface between Au/PTh-EDOT and DT/PTh-EDOT/ITO, CV is used. A scan rate is fixed at 50 mV/s, and 0.05 M of TBAP in an acetonitrile solution is used as an electrochemical probe to test the interface. Referring to FIGS. 8A to 8D, a current value of DT/Au/PTh-EDOT/ITO is decreased comparing with Au/PTh-EDOT/ITO. Electroactive ions exist at low concentration on a surface of DT/Au/PTh-EDOT/ITO because 1-decanthiol (DT) generates an insulating film that plays a role of a barrier against electron transfer at an interface of an electrode on a surface of Au/PTh-EDOT/ITO.

While the present invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A biosensor for detecting a thiol group, the biosensor where indium tin oxide (ITO), poly (thiophene-co-3,4-ethylenedioxythiophene) (PTh-EDOT), and Au nano particle films are sequentially laminated on.

2. The biosensor of claim 1, wherein the detecting a thiol group is performed by intercombination between thiol groups and gold nano particles.

3. The biosensor of claim 1, wherein the detecting is performed using cyclic voltammetry (CV).

4. A method of manufacturing a biosensor for detecting a thiol group, the method comprising:
manufacturing Au nano particles by irradiating radiation (Step 1);
manufacturing a PTh-EDOT/ITO film by forming a poly(thiophene-co-3,4-ethylenedioxythiophene) (PTh-EDOT) layer on an indium tin oxide (ITO) coated substrate using cyclic voltammetry (CV) (Step 2); and
manufacturing an Au nano particles modified PTh-EDOT/ITO film by dispersing the Au nano particles manufactured in Step 1 onto the PTh-EDOT/ITO film manufactured in Step 2 (Step 3).

5. The method of claim 4, wherein the manufacturing Au nano particles in Step 1 is performed using polyvinylpyrrolidine (PVP) that is a nano particle stabilizer polymer.

6. The method of claim 4, wherein the radiation in Step 1 is γ-ray of Co-60.

7. The method of claim 4, wherein the irradiating radiation in Step 1 has a dose rate of 6×10⁵ to 7×10⁵ Gy/h, adding up to a total absorption dose rate of 25 to 35 kGy.

8. The method of claim 4, wherein the Au nano particles in Step 1 are manufactured by mixing HAuCl₄, PVP, and isopropanol.

9. The method of claim 4, the CV in Step 2 is performed within a voltage range of +1.0 to +2.5 V.

10. The method of claim 4, wherein the PTh-EDOT in Step 2 is manufactured by mixing Th-EDOT (thiophene-co-3,4-ethylenedioxythiophene) monomers with tetrabutylammonium perchlorate (TBAP) at a one to one molar ratio.

11. The method of claim 10, wherein the Th-EDOT monomers has a molar ratio of Th(thiophene) to EDOT (ethylenedioxythiophene) as 4˜6:1.

12. The method of claim 4, wherein the modifying the PTh-EDOT/ITO film with the Au nano particles in Step 3 is performed using one of a chemical adsorption method and an electrochemical reduction method.

13. The method of claim 12, wherein the electrochemical reduction method is performed using cyclic voltammetry (CV) within a voltage range of −12.5 to −3.0 V using an Au salt solution.
